(19) United States
(12) Patent Application Publication
(10) Pub. No.: US 2011/0232383 A1
(43) Pub. Date: Sep. 29, 2011

(54) VIBRATION PIECE, ANGULAR VELOCITY SENSOR, AND ELECTRONIC APPARATUS

(75) Inventor: Masashi SHIMURA, Suwa (JP)

(73) Assignee: SEIKO EPSON CORPORATION, Tokyo (JP)

(21) Appl. No.: 13/024,578

(22) Filed: Feb. 10, 2011

(30) Foreign Application Priority Data
Mar. 29, 2010 (JP) 2010-074983

(51) Int. Cl. G01C 19/56; H01L 41/053; H02N 11/00; H01L 41/113; H01L 41/047

(52) U.S. Cl. 73/504.12; 310/348; 310/300

(57) ABSTRACT

A vibration piece includes: a base portion; a first driving arm which extends in a first axis direction from one end of the base portion in the first axis direction; a second driving arm which extends in the first axis direction from the other end of the base portion in the first axis direction; driving electrodes which are respectively provided in the first driving arm and the second driving arm; a detection arm which extends in a second axis direction perpendicular to the first axis direction from the base portion; a detection electrode which is provided in the detection arm; and a support portion which extends from the base portion, wherein the support portion is provided so as to surround the detection arm.

### BACKGROUND

1. Technical Field

The present invention relates to a vibration piece including a driving arm and a detection arm and used to detect an angular velocity of an object by detecting a vibration or a displacement thereof, an angular velocity sensor using the vibration piece, and an electronic apparatus using the angular velocity sensor.

2. Related Art

In recent years, a vibration gyro sensor (hereinafter, referred to as a vibration gyro) has been widely used as an angular velocity sensor that realizes a vehicle body control function of a vehicle, an own vehicle position detection function of a car navigation system, a vibration control correction function (so-called hand shaking correction function) of a digital camera or a digital video camera, and the like. The vibration gyro is designed to obtain a displacement of an object in such a manner that an electric signal generated in a part of a gyro vibration piece in accordance with a vibration such as a shaking or a rotation of an object is detected as an angular velocity by using the gyro vibration piece formed of a piezoelectric single crystal substance such as crystal which is a highly elastic material, and a rotation angle thereof is calculated.

Recently, in an electronic apparatus equipped with the vibration gyro, higher sensitivity for realizing the highly precise detection of the angular velocity has been strongly demanded as the demand for the high function has become higher, and a decrease in the size such as a decrease in the thickness (height) or area has been strongly demanded as the size of the electronic apparatus has become smaller.

For some time, a so-called tuning fork type piezoelectric vibration piece has been widely used as a vibration piece (gyro element) used in the vibration gyro (for example, refer to JP-A-5-256723). The vibration piece disclosed in JP-A-5-256723 includes a base portion formed of crystal and a pair of vibration arms respectively extending from one end of the base portion and divided into two branches so as to be parallel to each other. A driving electrode (excitation electrode) is provided on a first surface of each vibration arm so as to supply a driving voltage for exciting the vibration arm, and a detection electrode is provided on a side surface perpendicular to the first surface. Further, the vibration arm may be vibrated by applying a driving signal (excitation signal) to the driving electrode. Here, if a rotation about the axis of the extension direction of the vibration arm as a detection axis is applied when the driving signal is applied to the vibration piece so as to generate a vibration (in-plane vibration) in the vibration arm in a direction along the first surface, a vibration (out-of-plane vibration) of the vibration arm in a direction perpendicular to the first surface is generated due to Coriolis force. Since the amplitude of the out-of-plane vibration is proportional to the rotation velocity of the vibration piece, the amplitude may be detected as an angular velocity.

The vibration gyro has a structure in which an IC chip as an electronic component, including a vibration piece, a driving circuit driving and vibrating the vibration piece, and a detection circuit detecting a detection vibration generated in the vibration piece when an angular velocity is applied thereto, is air-tightly sealed inside a package as a base substrate. That is, for example, the vibration gyro has the structure of the piezoelectric vibration device including the piezoelectric vibration piece which has been widely used for some time (for example, refer to JP-A-2006-54602).

The piezoelectric vibration device (crystal oscillator) disclosed in JP-A-2006-54602 has a structure in which a vibration piece (piezoelectric vibration plate) and an IC chip (integrated circuit element) as an electronic component constituting an oscillation circuit along with the vibration piece are bonded to the inside of a package (ceramic package), and are air-tightly sealed.

A package base constituting an accommodation portion of the package includes a concave portion having an opened upper portion. Further, the concave portion is provided with plural steps, an IC chip is bonded to a lower accommodation portion formed by one of the steps by wire bonding or the like, and the vibration piece is bonded to an upper accommodation portion formed by the other steps by, for example, a bonding member such as a conductive adhesive.

However, in the configuration of the gyro vibration piece disclosed in JP-A-5-256723, since the angular velocity of the rotation about only one detection axis may be detected, for example, the vibration piece needs to be disposed in the perpendicular direction so as to detect the angular velocities of the rotations about the other detection axes. Further, since plural vibration pieces need to be provided in one angular velocity sensor in order to realize the detection of the angular velocities of the rotations about plural detection axes using one angular velocity sensor, there is a problem in that it is difficult to realize a decrease in the size such as a decrease in the height or area of the angular velocity sensor.

Further, in the configuration of the gyro vibration piece disclosed in JP-A-5-256723, since the driving electrode and the detection electrode are disposed close to each other in the same vibration arm, there is a problem in that the detection precision may be degraded due to the combination of the driving vibration and the detection vibration.

### SUMMARY

An advantage of some aspects of the invention is to solve at least a part of the problems described above, and the invention can be implemented as the following forms or application examples.

### Application Example 1

According to this application example of the invention, there is provided a vibration piece including: a base portion; a first driving arm which extends in a first axis direction from one end of the base portion in the first axis direction; a second driving arm which extends in the first axis direction from the other end of the base portion in the first axis direction; driving electrodes which are respectively provided in the first driving arm and the second driving arm; a detection arm which extends in a second axis direction perpendicular to the first axis direction from the base portion; a detection electrode which is provided in the detection arm; and a support portion which extends from the base portion, wherein the support portion is provided so as to surround the detection arm.

The vibration piece of the application example may be used in an angular velocity sensor. According to the vibration piece of the application example, since the vibration piece includes the first and second driving arms respectively extending in the first axis direction and the detection arm extending in the second axis direction perpendicular to the first axis direction, for example, it is possible to detect the bending of the detection arm caused by Coriolis force in the out-of-plane vibration direction and the in-plane vibration direction perpendicular to the in-plane-vibration direction of the first and second driving arms while the first and second driving arms are vibrated (in an in-plane vibration manner) with the element within the same plane. Accordingly, since it is possible to detect the angular velocities of the rotations about plural detection axes while the vibration piece is disposed in the horizontal direction by using one vibration piece, it is possible to realize the detection of the angular velocity with respect to plural detection axes while ensuring a decrease in the size such as a decrease in the height and area.

Further, since the first and second driving arms and the detection arm are disposed so as to be perpendicular to each other without being close to each other, it is possible to highly precisely detect the angular velocity while preventing degradation in the detection precision caused by the combination of the driving vibration and the detection vibration.

### Application Example 2

In the vibration piece of the application example, the vibration piece may be formed of a piezoelectric material.

By using the piezoelectric material which has been widely used as a material of the vibration piece for some time, for example, it is possible to provide the high-performance piezoelectric vibration piece having a piezoelectric effect obtained by known principles or know-how.

### Application Example 3

In the vibration piece of the application example, the piezoelectric material may be crystal.

It is possible to suppress a degradation of the temperature characteristics (temperature dependency such as frequency characteristics) in accordance with a decrease in the size of the vibration piece by using crystal.

### Application Example 4

In the vibration piece of the application example, each of the driving electrodes and the detection electrode may be a laminated structure including a first electrode, a second electrode, and a piezoelectric layer provided between the first electrode and the second electrode. Two laminated structures may be provided on each of the first driving arm, the second driving arm, and the detection arm so as to be parallel to each other in the extension direction of each arm, the first electrode of one laminated structure may be electrically connected to the second electrode of the other laminated structure, and the second electrode of one laminated structure may be electrically connected to the first electrode of the other laminated structure.

According to this configuration, since AC voltages having reverse phases are applied to two driving electrodes in the driving arm, the electric field component not contributing to the driving is reduced, and the free expansion/contraction of the driving arm is hardly disturbed, thereby improving the driving efficiency.

Further, in the detection arm, the first and second electrodes of each of two detection electrodes are electrically separated from each other in order to detect the angular velocities of the rotations about plural detection axes. Even in the detection arm, since the free expansion/contraction of the detection arm is hardly disturbed due to the same configuration as that of the driving electrode, it is possible to improve the detection sensitivity with respect to the applied angular velocity.

### Application Example 5

In the vibration piece of the application example, the detection electrode may be a pair of comb-shaped electrodes.

According to this configuration, since it is possible to greatly reduce spurious responses by emphasizing the responses of the desired vibration mode, for example, it is possible to provide the vibration piece for the angular velocity sensor capable of measuring the angular velocity with high precision.

### Application Example 6

According to this application example of the invention, there is provided an angular velocity sensor including: the vibration piece according to the above-described application example; a driving section which drives the first and second driving arms in the same direction along the second axis direction; and a detection section which detects a voltage, generated by a vibration generated in a third axis direction perpendicular to the first axis direction and the second axis direction in the detection arm when the rotation about the first axis is performed at the time of the driving operation, through the detection electrode.

According to this configuration, since the movement energy during the driving vibration may be preserved and the gravity center may be supported, it is possible to reduce the influence of the vibration leakage to the support portion. Accordingly, it is possible to realize the angular velocity sensor with high detection sensitivity.

### Application Example 7

According to this application example of the invention, there is provided an angular velocity sensor including: the vibration piece according to the above-described application example; a driving section which drives the first and second driving arms in the same direction along the second axis direction; and a detection section which detects a voltage, generated by a vibration generated in the first axis direction in the detection arm when the rotation about a third axis perpendicular to the first axis direction and the second axis direction is performed at the time of the driving operation, through the detection electrode.

According to this configuration, since the movement energy during the driving vibration may be preserved and the gravity center may be supported, it is possible to reduce the influence of the vibration leakage to the support portion. Accordingly, it is possible to realize the angular velocity sensor with high detection sensitivity.

### Application Example 8

According to this application example of the invention, there is provided an electronic apparatus including the vibration piece according to the above-described application example.

According to this configuration, since the vibration piece according to the above-described application example is mounted on the angular velocity sensor, it is possible to provide the electronic apparatus having the angular velocity sensor capable of realizing a decrease in the size and height and improving the detection sensitivity without disposing the vibration piece in an upright manner.

### BRIEF DESCRIPTION OF THE DRAWINGS

The invention will be described with reference to the accompanying drawings, wherein like numbers reference like elements.

FIG. 1 is a schematic plan view illustrating an embodiment of a vibration piece when viewed from one main surface thereof.

FIG. 2A is a cross-sectional view illustrating the structure of electrodes of the vibration piece when viewed taken along the line A-A of FIG. 1, and FIG. 2B is a cross-sectional view taken along the line B-B.

FIG. 3A is a schematic plan view illustrating a mode of the operation of the vibration piece, and FIG. 3B is a schematic plan view illustrating another mode of the operation of the vibration piece.

FIG. 4A is a schematic plan view illustrating an embodiment of a vibration gyro which is an angular velocity sensor when viewed from the upside thereof, and FIG. 4B is a schematic cross-sectional view taken along the line C-C of FIG. 4A.

FIG. 5 is a schematic plan view illustrating a modified example of the vibration piece when viewed from the upside thereof.

FIG. 6A is a schematic plan view illustrating a mode of the operation of the vibration piece of the modified example, and FIG. 6B is a schematic plan view illustrating another mode of the operation of the vibration piece.

### DESCRIPTION OF EXEMPLARY EMBODIMENTS

Hereinafter, the preferred embodiment of the invention will be described with reference to the accompanying drawings.

### Vibration Piece

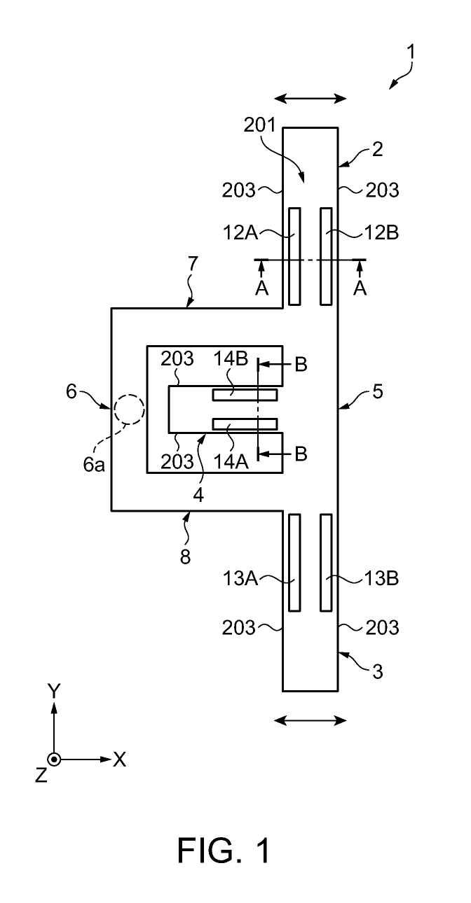

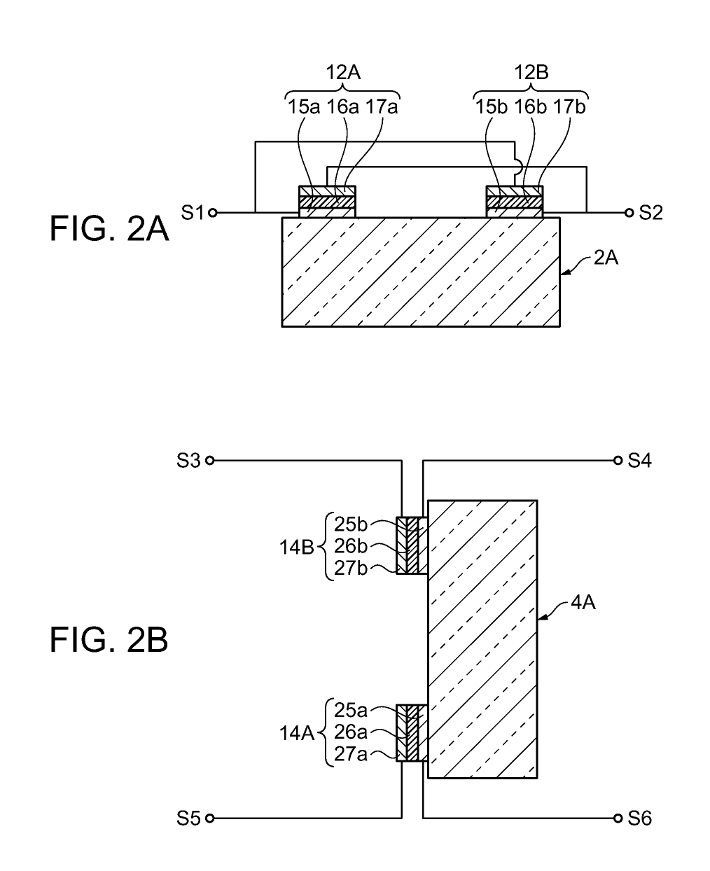

First, a vibration piece 1 of the embodiment will be described with reference to the drawings. FIG. 1 is a schematic plan view illustrating the vibration piece 1 when viewed from one main surface (first surface) thereof. FIGS. 2A and 2B are diagrams illustrating the structure of the electrodes of the vibration piece 1, where FIG. 2A is a cross-sectional view taken along the line A-A of FIG. 1, and FIG. 2B is a cross-sectional view taken along the line B-B of FIG. 1.

Further, in the following description, the shape or the like of the vibration piece 1 will be first described, and then the arrangement or the like of the terminals, the wirings, and the electrodes formed on the vibration piece 1 will be described. Then, the operation of the vibration piece 1 will be described.

### Shape or the Like of Vibration Piece

The vibration piece 1 is formed of a highly elastic material, for example, silicon or a piezoelectric material such as lithium niobate, lithium tantalite, and crystal. Particularly, it is desirable to use crystal since degradation of temperature characteristics (temperature dependency such as frequency characteristics) in accordance with a decrease in the size of the vibration piece may be suppressed. Further, in the case of the crystal, the X-cut plate having satisfactory temperature characteristics is desirable from the viewpoint of the cut angle, but the Z-cut plate (rotation X) and the AT-cut plate may be used. In the case of the Z-cut plate, etching is easily performed.

The vibration piece 1 is a so-called gyro element that is used in a vibration gyro in the embodiment.

As shown in FIGS. 1, 2A, and 2B, the vibration piece 1 has, for example, a plane (hereinafter, referred to as an XY plane) in which the first axis of the crystal axis is defined as the Y axis and the second axis thereof is defined as the X axis, and a thickness in the Z direction. The vibration piece 1 includes a first surface 201 (one main surface), a second surface (not shown) which is a surface facing the first surface 201, and a side surface 203 connecting the first surface 201 and the second surface to each other. The first surface 201 and the second surface are surfaces parallel to the XY plane in the drawing. Further, the side surface 203 is a surface which is perpendicular to the first surface 201 and the second surface and is parallel to the Z axis. In the description of the embodiment (including the modified example), the “X axis” will be used with the meaning of the X axis and the axis that is inclined by the range larger than 0° and equal to or less than 2° with respect to the X axis. The same applies to the “Y axis” and the “Z axis”.

The vibration piece 1 includes: a base portion 5; first and second driving arms 2 and 3 which respectively extend from both end portions of the base portion 5 by substantially the same length in the Y axis direction (the first axis direction); a detection arm 4 which extends from the side surface 203 of the base portion 5 in the X axis direction (the second axis direction) perpendicular to the first axis direction; and a support portion 6 which extends from the side surface 203 of the base portion 5 so as to surround the detection arm 4.

The support portion 6 includes: first and second connection bars 7 and 8 which respectively extend from the side surfaces (which is the same as the side surface 203 where the detection arm 4 extends) 203 of both end portions of the base portion 5 in the X axis direction so as to be longer than the detection arm 4; and a portion (hereinafter, referred to as the support portion 6) which extends in parallel to the base portion 5 and connects the front ends of the first and second connection bars 7 and 8 to each other.

The first and second driving arms 2 and 3 respectively extend in the positive and negative directions along the Y axis of the base portion 5. In the embodiment, the first driving arm 2 extends from one end of the base portion 5 in the positive direction of the Y axis toward the positive direction of the Y axis. The second driving arm 3 extends from the other end of the base portion 5 in the negative direction of the Y axis toward the negative direction of the Y axis.

The detection arm 4 extending from the base portion 5 in the X axis constitutes a detection vibration system that detects an angular velocity.

Further, the first and second driving arms 2 and 3 respectively extending from the base portion 5 toward the positive and negative sides of the Y axis constitute a driving vibration system that drives the vibration piece 1.

The first and second connection bars 7 and 8 extend from the end portion of the base portion 5 in the X axis along the X axis. Further, the detection arm 4 extends from the end portion in the X axis of the base portion 5 between the first and second connection bars 7 and 8 so as to be parallel to the first and second connection bars 7 and 8.

The support portion 6 is connected to the front ends of the first and second connection bars 7 and 8 in the Y axis direction where the front ends thereof are perpendicular to each other, and is disposed so as not to contact the detection arm 4, where the first and second connection arms extend from the base portion 5 in the X axis direction with the detection arm 4 interposed therebetween so as to be parallel to each other. The support portion 6 of the embodiment has a substantially rectangular shape that is thin and elongated in the plan view thereof, but the shape is not particularly limited.

Apart of the support portion 6 is used as, for example, a support area 6a that supports the vibration piece 1 and is a portion (area) bonded and fixed to a package accommodating the vibration piece 1. In the embodiment, the support portion 6 provided in parallel to the first driving arm 2, the base portion 5, and the second driving arm. 3 extending in the Y axis direction is provided with the support area 6a where the Y-axis-direction centers of three members, the first driving arm 2, the base portion 5, and the second driving arm 3 overlap with each other in the Y axis direction. That is, the vibration piece 1 is formed so as to be line-symmetrical to the imaginary central line passing through the centers of the support area 6a of the support portion 6, the detection arm 4, and the base portion 5 in the X axis direction. With this configuration, the connection body of the first driving arm 2, the base portion 5, and the second driving arm 3 extending in the Y axis direction may be supported by the support portion 6 with a good balance through the first and second connection bars 7 and 8.

Further, in the support structure of the vibration piece 1 using the support portion 6, the first connection bar 7, and the second connection bar 8, the shapes of the first connection bar 7, the second connection bar 8, and the support portion 6 are only an example of a structure that elastically supports the vibration piece 1, and the shapes may be appropriately modified so long as the elastic supporting purpose is achieved. As in the embodiment, according to the configuration in which the vibration piece 1 is supported by the support area 6a of the support portion 6 at one point, the free vibration of each component of the vibration piece 1 is hardly disturbed, and vibration leakage from the support portion (support area 6a) may be suppressed.

The external shape of the vibration piece 1 described above may be precisely formed by performing dry etching or wet etching using a hydrofluoric acid solution on, for example, a piezoelectric substrate material such as a crystal wafer.

Next, various electrodes or wirings of the vibration piece 1 will be described.

As shown in FIG. 1, a pair of first and second driving electrodes 12A and 12B is formed on the first surface 201 of the first driving arm 2 so as to be parallel to the Y axis direction of the first driving arm. In the same way, a pair of first and second driving electrodes 13A and 13B is formed on the first surface 201 of the second driving arm so as to be parallel to the Y axis direction of the second driving arm. The first driving electrodes 12A and 13A and the second driving electrodes 12B and 13B are electrodes that excite the first driving arm 2 or the second driving arm 3 in accordance with the driving voltage applied from the outside.

Further, a pair of first and second detection electrodes 14A and 14B is formed on the first surface 201 of the detection arm. 4 so as to be parallel to the X axis direction of the detection arm 4. The first and second detection electrodes 14A and 14B are electrodes that detect a bending of the detection arm 4 (for example, a piezoelectric material) generated in accordance with a vibration when the detection vibration of the detection arm 4 is excited.

Further, as in the vibration piece 1 of the embodiment, the first and second driving electrodes 12A, 13A, 12B, and 13B and the first and second detection electrodes 14A and 14B are formed to be line-symmetrical to each other with respect to the central line of each arm of the first driving arm 2, the second driving arm 3, and the detection arm 4. Accordingly, the driving electric field generated in the first and second driving arms 2 and 3 or the electric field detected in the detection arm 4 has a good balance, and vibration leakage hardly occurs in directions other than a predetermined vibration direction, which is desirable in that the driving efficiency is further improved.

Although not shown in the drawings, the first and second driving electrodes 12A, 13A, 12B, and 13B and the first and second detection electrodes 14A and 14B are electrically connected to an external connection electrode provided in the support area 6a of the support portion 6, a grounding electrode provided at an arbitrary position of the vibration piece 1, or the corresponding electrode through an inter-electrode wiring formed on the first surface 201 or the second surface of the vibration piece 1 or an inter-electrode wiring formed on the side surface 203, thereby forming the wiring circuit of the vibration piece 1.

Next, the detailed configuration of the electrodes formed on the first driving arm 2, the second driving arm 3, and the detection arm 4 will be described with reference to FIGS. 2A and 2B.

As shown in FIG. 2A, the pair of first and second driving electrodes 12A and 12B formed on the first surface 201 of the first driving arm 2 are formed by the laminated structure including first electrodes 15a and 15b formed on the first surface 201 of the first driving arm 2, piezoelectric layers 16a and 16b respectively formed on the first electrodes 15a and 15b, and second electrodes 17a and 17b respectively formed on the piezoelectric layers 16a and 16b.

In the pair of first and second driving electrodes 12A and 12B of the first driving arm 2, the first electrodes 15a and 15b respectively face the second electrodes 17a and 17b with the piezoelectric layers 16a and 16b interposed therebetween, and the first electrodes 15a and 15b and the second electrodes 17a and 17b are disposed so as to have different polarities. Further, the first driving electrode 12A and the second driving electrode 12B are electrodes having reversed phases.

In the embodiment, the first electrode 15a of the first driving electrode 12A and the second electrode 17b of the second driving electrode 12B are electrodes having the same phase and connected to the same connection terminal portion S1, and the second electrode 17a of the first driving electrode 12A and the first electrode 15b of the second driving electrode 12B are electrodes having the same phase and connected to the same connection terminal portion S2. Although not shown in FIG. 1, the connection terminal portions S1 and S2 are provided in, for example, the support area 6a of the support portion 6, and are connected to the corresponding electrodes through the inter-electrode wirings provided on the first surface 201 of the vibration piece 1 or the side surface 203.

Further, although not shown in the drawings, the pair of first and second driving electrodes 13A and 13B (refer to FIG. 1) formed on the first surface 201 of the second driving arm 3 making a pair with the first driving arm 2 has the same electrode structure as that of the first and second driving electrodes 12A and 12B of the first driving arm 2.

According to the configuration in which the first and second driving electrodes 12A, 13A, 12B, and 13B having a laminated structure including the piezoelectric layers 16a and 16 are disposed in parallel while being distant from each other with respect to the central line as the boundary in the Y direction, when AC voltages having reversed phases are applied to the first driving electrodes 12A and 13A and the second driving electrodes 12B and 13B, the electric field component not contributing to the driving may be reduced, and the free expansion/contraction of the first and second driving arms 2 and 3 is hardly disturbed, thereby improving the driving efficiency.

As shown in FIG. 2B, the pair of first and second detection electrodes 14A and 14B provided on the first surface 201 of the detection arm 4 is constituted by first electrodes 25a and 25b formed on the first surface 201 of the detection arm 4, piezoelectric layers 26a and 26b respectively formed on the first electrodes 25a and 25b, and second electrodes 27a and 27b respectively formed on the piezoelectric layers 26a and 26b.

In the pair of first and second detection electrodes 14A and 14B of the detection arm 4, the first electrodes 25a and 25b face the second electrodes 27a and 27b with the piezoelectric layers 26a and 26b interposed therebetween, where the first electrodes 25a and 25b and the second electrodes 27a and 27b are disposed so as to have different polarities. Further, the first detection electrode 14A and the second detection electrode 14B are electrodes having the same phase.

Accordingly, the first and second electrodes are drawn to individual connection terminal portions. In the embodiment, the first electrode 25a of the first detection electrode 14A is connected to the connection terminal portion S6, the second electrode 27a is connected to the connection terminal portion S5, the first electrode 25b of the second detection electrode 14B is connected to the connection terminal portion S4, and the second electrode 27b is connected to the connection terminal portion S3. Although not shown in FIG. 1, the connection terminal portions S3 to S6 are provided in, for example, the support area 6a of the support portion 6, and are connected to the corresponding electrodes through the inter-electrode wirings provided on the first surface 201 of the vibration piece 1 or the side surface 203 thereof.

According to the configuration in which two first and second detection electrodes 14A and 14B having the laminated structure including the piezoelectric layers 26a and 26b are disposed in parallel while being distant from each other with respect to the central line as the boundary in the X direction of the detection arm 4, since the free expansion/contraction of the detection arm 4 is hardly disturbed, the detection sensitivity for the applied angular velocity is improved.

### Operation of Vibration Piece

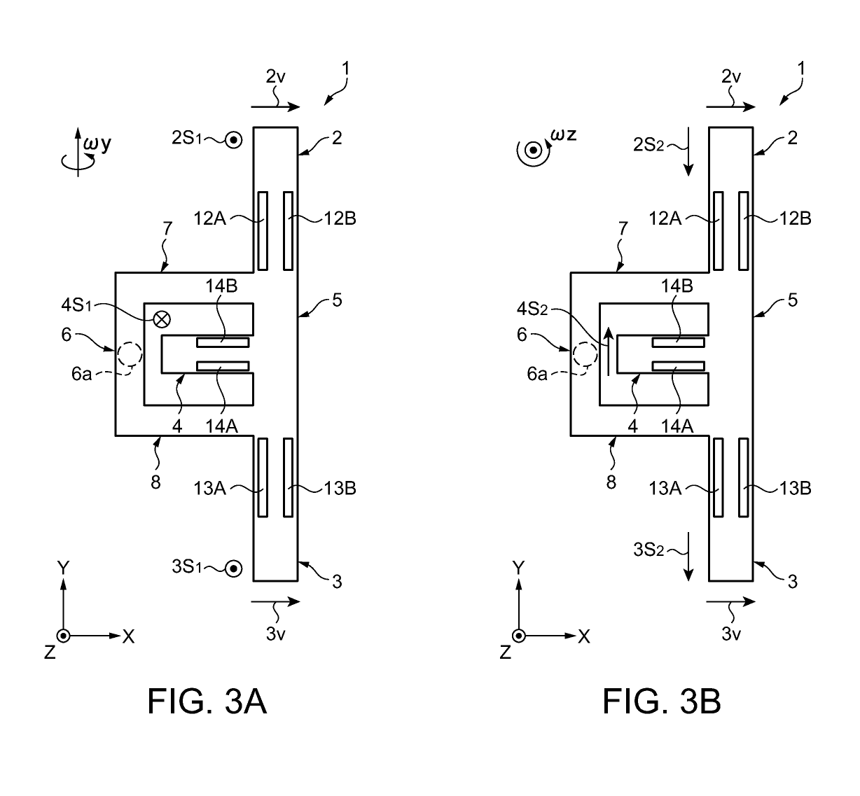

Next, an exemplary mode of the vibration piece 1 will be described with reference to the drawings. FIGS. 3A and 3B are schematic plan views illustrating exemplary modes of the operation of the vibration piece 1. Further, in the following description of the operation of the vibration piece 1, FIGS. 2A and 2B are also to be used as a reference.

First, an excitation signal is input to the first driving electrode 12A and the second driving electrode 12B of the first driving arm. 2 of the vibration piece 1 shown in FIGS. 2A and 2B. Specifically, a positive potential (or a negative potential) is input to the first electrode 15a of the first driving electrode 12A and the second electrode 17b of the second driving electrode 12B through the connection terminal portion S1, and a negative potential (or a positive potential) is input to the second electrode 17a of the first driving electrode 12A and the first electrode 15b of the second driving electrode 12B through the connection terminal portion S2.

Then, as shown in FIG. 3A, an electric field in the reverse direction is generated between the second electrode and the first electrode of each of the first driving electrode 12A and the second driving electrode 12B, and stretching or compressing in the Y direction is generated in each electrode. That is, when the stretching (+Y) is generated in the first driving electrode 12A, the compressing (−Y) is generated in the second driving electrode 12B. When the compressing (−Y) is generated in the first driving electrode 12A, the stretching (+Y) is generated in the second driving electrode 12B.

Likewise, when the stretching or the compressing of the positive/negative stretching/compressing of the first and second driving electrodes 12A and 12B disposed on the first driving arm 2 while being distant from each other with respect to the central line as the boundary in the Y direction is repeated by inputting an AC signal thereto, the vibration of the first driving arm 2 in the ±X direction is repeated.

Further, when the same signal as that of the AC signal input to the first and second driving electrodes 12A and 12B of the first driving arm 2 is input to the first and second driving electrodes 13A and 13B of the second driving arm 3, the vibration is repeated in the same ±X direction as that of the first driving arm 2.

Here, as shown in FIGS. 3A and 3B, the mode of the operation of the vibration piece 1 when the first and second driving arms 2 and 3 are vibrated in a direction (+X direction) depicted by the arrows 2v and 3v will be described in detail.

First, as shown in FIG. 3A, if a counter-clockwise rotation ωy about the Y axis is applied to the vibration piece 1 when the first and second driving arms 2 and 3 are vibrated in a direction (+X direction) depicted by the arrows 2v and 3v, Coriolis force is generated in a direction (+Z direction) depicted by the reference numerals 2S1 and 3S1 perpendicular to the direction of the vibration (in-plane vibration) of the first and second driving arms 2 and 3.

Accordingly, the vibration (out-of-plane vibration) is generated in the detection arm 4 in a direction (−Z direction) depicted by the reference numeral 4S1 perpendicular to the first surface 201 (refer to FIG. 1). When the amount of charge (voltage) generated by the electric field component of the detection arm 4 in accordance with the out-of-plane vibration is measured by the first and second detection electrodes 14A and 14B, the angular velocity when the rotation about the Y axis is applied to the vibration piece 1 may be obtained.

On the other hand, as shown in FIG. 3B, if a counter-clockwise rotation ωz about the Z axis is applied to the vibration piece 1 when the first and second driving arms 2 and 3 are vibrated in a direction (+X direction) depicted by the arrows 2v and 3v, Coriolis force is generated in a direction (−Y direction) depicted by the arrows 2S2 and 3S2 perpendicular to the direction of the vibration (in-plane vibration) of the first and second driving arms 2 and 3.

Accordingly, the vibration (in-plane vibration) is generated in the detection arm 4 in a direction (+Y direction) depicted by the arrow 4S2 perpendicular to the first surface 201 (refer to FIG. 1), and the compressing or stretching in the reverse direction is generated in the first and second detection electrodes 14A and 14B of the detection arm 4 in accordance with the in-plane vibration. When a difference in the amount of charge generated by the compressing or stretching of the first and second detection electrodes 14A and 14B is measured and calculated, the angular velocity when the rotation about the Z axis is applied to the vibration piece 1 may be obtained.

Therefore, according to the vibration piece 1 of the embodiment, when the vibration in the ±X direction is repeated by inputting an excitation signal to the first and second driving arms 2 and 3, the angular velocities of the rotations about plural detection axes may be detected by one vibration piece 1 in accordance with the rotation about two detection axes of Y and Z axes.

Accordingly, the angular velocities of the rotations about plural detection axes may be detected while the vibration piece 1 is horizontally disposed inside a package or the like.

Further, according to the vibration piece 1 of the embodiment, since the first and second driving arms 2 and 3 and the detection arm 4 are disposed so as to be perpendicular to each other through the base portion 5 without being disposed close to each other, it is possible to provide the vibration piece 1 capable of preventing the degradation of the detection precision caused by the combination of the driving vibration and the detection vibration and detecting the angular velocity with high precision.

### Vibration Gyro

Next, a vibration gyro as an angular velocity sensor including the vibration piece 1 will be described with reference to the drawings.

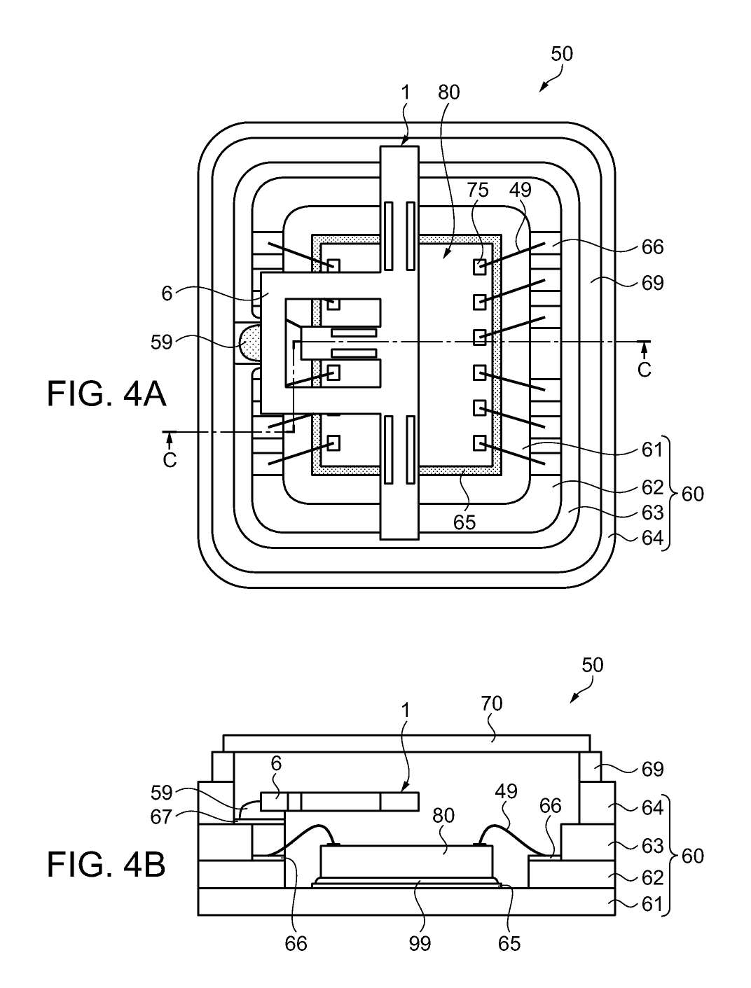

FIGS. 4A and 4B illustrates an embodiment of a vibration gyro, where FIG. 4A is a schematic plan view when viewed from the upside thereof, and FIG. 4B is a schematic cross-sectional view taken along the line C-C of FIG. 4A. Further, for convenience of description in the internal structure of the vibration gyro, FIG. 4A shows a state where a lid 70 as a cover provided on the upper portion of the vibration gyro is removed.

Further, in the vibration gyro 50 according to the embodiment, since the same reference numerals are given to the same components having the same functions as those of the vibration piece 1 according to the embodiment, the detailed description thereof will be omitted and a part of the members are not shown.

As shown in FIGS. 4A and 4B, the vibration gyro 50 includes a package 60; a lid 70 which is a cover of the package 60; an IC chip 80 which is an electronic component bonded to the inside of the package; and the vibration piece 1.

For example, the package 60 includes a concave portion with a step or a protrusion portion by laminating a second layer substrate 62 having a rectangular annular shape, a third layer substrate 63, and a fourth layer substrate 64 respectively having different sizes of opening portions on a flat-plate-shaped first layer substrate 61, and the concave portion may accommodate the vibration piece 1 and the IC chip 80. Examples of the material of the package 60 include ceramics, glass, and the like.

A die pad 65 is provided on the first layer substrate 61 which is a concave bottom portion of the concave portion of the package 60 so that the IC chip 80 is disposed thereon. Further, the outer bottom surface of the package 60 as the opposite side of the die pad 65 of the first layer substrate 61 is provided with an external mounting terminal (not shown) that is used for bonding to the external substrate.

Plural IC connection terminals 66 bonded to plural corresponding electrode pads 75 of the IC chip 80 are provided on the step formed to surround the die pad 65 by the second layer substrate 62 in the concave portion of the package 60.

In addition, a vibration piece connection terminal 67 is provided on the step formed by the third layer substrate 63 to surround the IC connection terminal 66 on the second layer substrate 62 provided with plural IC connection terminals 66.

In the above-described various terminals provided in the package 60, the corresponding terminals are connected to each other through an intra-layer wiring such as a routing wiring and a through hole (not shown).

The IC chip 80 includes a driving circuit which is an exciting section (a driving section) for driving (vibrating) the vibration piece 1 and a detection circuit which is a detection section for detecting the vibration generated in the vibration piece 1 when an angular velocity is applied. Specifically, the driving circuit included in the IC chip 80 supplies a driving signal to the first and second driving electrodes 12A, 13A, 12B, and 13B formed on the first and second driving arms 2 and 3 of the vibration piece 1. Further, the detection circuit included in the IC chip 80 amplifies a detection signal generated in the first and second detection electrodes 14A and 14B formed in the detection arm 4 of the vibration piece 1 so as to generate an amplified signal, and detects the angular velocity applied to the vibration gyro 50 on the basis of the amplified signal.

The IC chip 80 is bonded and fixed onto the die pad 65 provided in the concave bottom portion of the concave portion of the package 60 by, for example, a brazing material 99. Further, in the embodiment, the IC chip 80 and the package 60 are electrically connected to each other by wire bonding. That is, plural electrode pads 75 provided in the IC chip 80 and the corresponding IC connection terminals 66 of the package 60 are electrically connected to each other by bonding wires 49.

The vibration piece 1 is bonded to the upper portion of the IC chip 80 inside the concave portion of the package 60. Specifically, the external connection electrodes formed on the support portion 6 (the support area 6a of FIG. 1) of the vibration piece 1 are positioned on the vibration piece connection terminals 67 provided on the step formed by the third layer substrate 63 of the package 60, and are bonded and fixed to each other while being electrically connected to each other by a bonding member 59 such as a conductive adhesive. Accordingly, the vibration piece 1 is supported in a cantilever manner with the support portion 6 serving as a fixed end.

The lid 70 as a cover is disposed on the package 60 to which the IC chip 80 and the vibration piece 1 are bonded, thereby sealing the opening of the package 60. Examples of the material of the lid 70 include glass, ceramic, or metal such as kovar (alloy of iron, nickel, and cobalt) and 42 alloy (alloy having 42% of nickel in iron). For example, the lid 70 formed of metal is bonded to the package 60 by seam welding through a seal ring 69 formed by a rectangular annular die formed of kovar alloy. The concave space formed by the package 60 and the lid 70 is a space for operating the vibration piece 1.

In the vibration gyro 50 according to the embodiment, the concave space may be hermetically sealed as a depressurization space or as the atmosphere of inert gas. For example, when the concave space is hermetically sealed as a depressurization space, for example, a spherical solid sealing material is disposed in a sealing hole (not shown) provided in the package 60, and is inserted into a vacuum chamber. Then, the pressure is decreased to a predetermined vacuum degree so as to discharge a gas emitted from the inside of the vibration gyro 50 through the sealing hole, and an electron beam or a laser is irradiated thereto to melt and solidify the sealing material, thereby blocking and sealing the sealing hole. Further, it is desirable to use a sealing material having a melting point higher than the reflow temperature when mounting the completed vibration gyro 50 on the external mounting substrate. For example, alloy of gold and tin (Sn) or alloy of gold and germanium (Ge) may be used.

According to the vibration gyro 50 of the embodiment, since the above-described vibration piece 1 is provided, it is possible to highly sensitively detect the angular velocities about two detection axes without disposing the vibration piece 1 in the longitudinal direction. Therefore, it is possible to realize the vibration gyro 50 which is an angular velocity sensor having high detection sensitivity and realizing a decrease in height.

The vibration gyro as the angular velocity sensor described in the above-described embodiment may be modified in accordance with the following modified example.

### Modified Example

The vibration piece 1 of the above-described embodiment includes the pair of first and second driving arms 2 and 3 and one detection arm 4, but the invention is not limited thereto. For example, the vibration piece may include an arbitrary number n of combinations, that is, n pairs of driving arms and n detection arms.

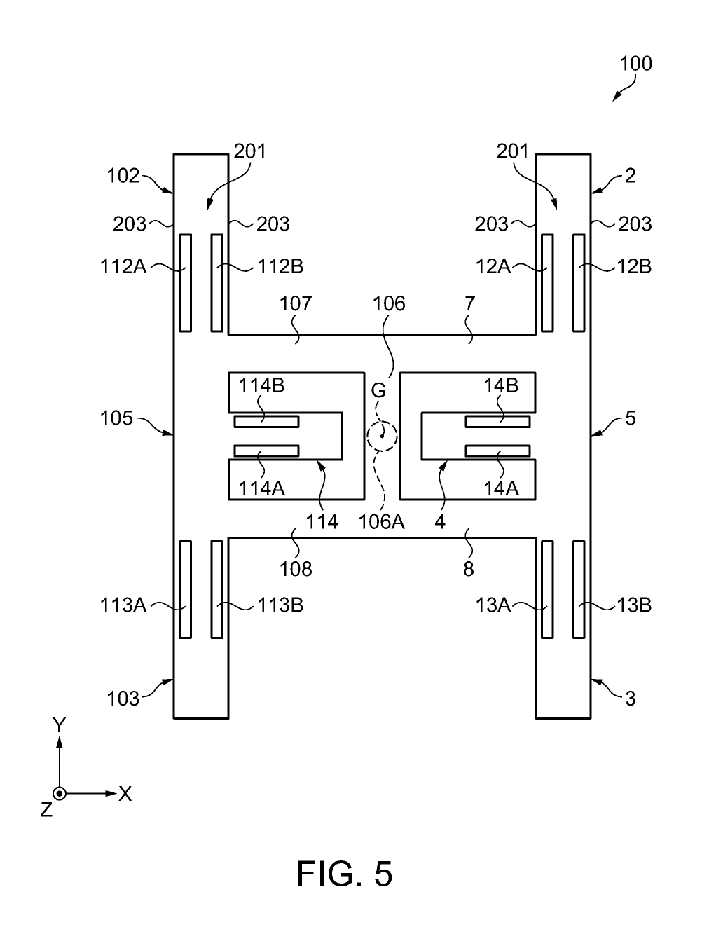

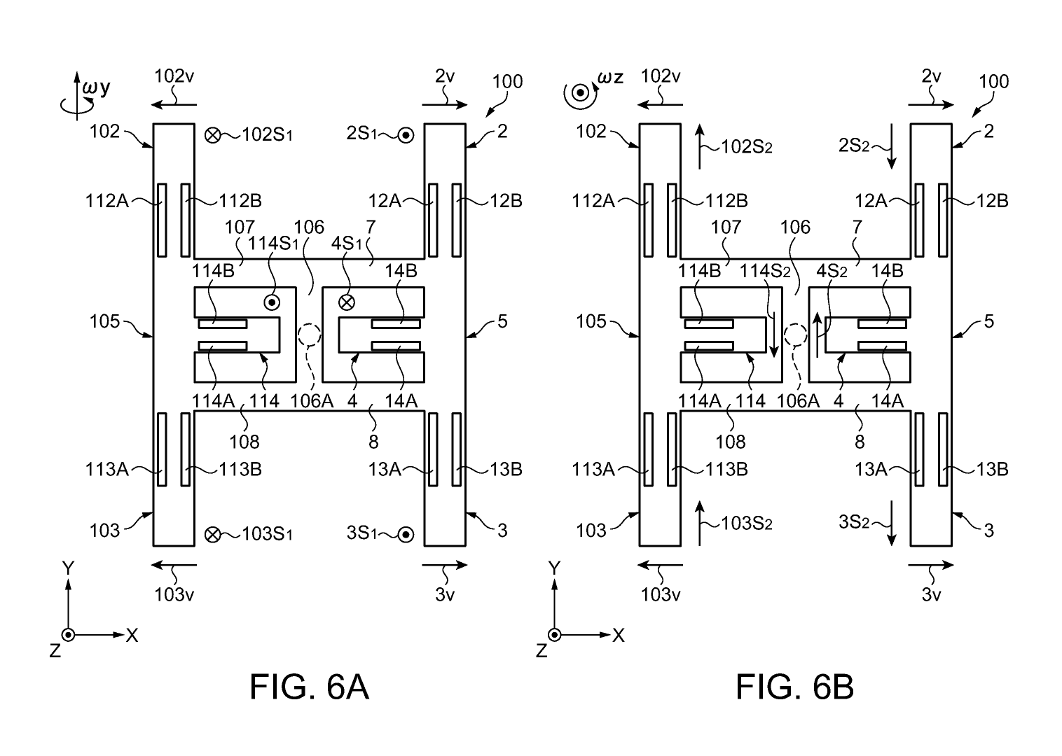

FIG. 5 is a schematic plan view illustrating a modified example of the vibration piece including two pairs of driving arms and two detection arms. Further, FIGS. 6A and 6B are schematic plan views respectively illustrating exemplary modes of the operation of the vibration piece of the modified example. In the description of the modified example, since the same reference numerals are given to the same components, the description thereof is omitted.

In FIG. 5, a vibration piece 100 of the modified example includes: the base portion (first base portion) 5; the first and second driving arms 2 and 3 which respectively extend from both end portions of the base portion 5 in the first axis direction by substantially the same length in the first axis direction (the Y axis direction); the detection arm (first detection arm) 4 which extends from the side surface 203 of the base portion 5 in the second axis direction (the X axis direction) perpendicular to the first axis direction; and a support portion 106 which extends from the side surface where the detection arm 4 of the base portion 5 extends so as to surround the detection arm 4.

The support portion 106 includes: the first and second connection bars 7 and 8 which respectively extend so as to be longer than the detection arm 4 in the X axis direction; a portion (hereinafter, referred to as the support portion 106) which connects the front ends of the first and second connection bars 7 and 8 to each other; and third and fourth connection bars 107 and 108 to be described later.

Then, the vibration piece 100 includes: the third and fourth connection bars 107 and 108 which respectively extend from the first and second connection bars 7 and 8; a second base portion 105 which extend in parallel to the (first) base portion 5 so as to connect the front end portions of the third and fourth connection bars 107 and 108; third and fourth driving arms 102 and 103 which respectively extend from both end portions of the second base portion 105 in the first axis direction by substantially the same length in the first axis direction; and a second detection arm 114 which extends in the second axis direction from the side surface where the third and fourth connection bars 107 and 108 of the second base portion 105 are connected to each other.

The second detection arm 114 is surrounded by the support portion 106 (including the third and fourth connection bars 107 and 108).

Various electrodes provided on the first surface 201 of the first driving arm 2, the second driving arm 3, and the (first) detection arm 4 of the vibration piece 100 have the same configuration as that of the above-described embodiment. In the same way, various electrodes are provided on the first surface 201 of each of the third driving arm 102, the fourth driving arm 103, and the second detection arm 114.

Specifically, a pair of first and second driving electrodes 112A and 112B is formed on the first surface 201 of the third driving arm 102 so as to be parallel to the longitudinal direction (the Y axis direction) of the third driving arm 102. A pair of first and second driving electrodes 113A and 113B is formed on the first surface 201 of the fourth driving arm so as to be parallel to the longitudinal direction of the fourth driving arm 103. A pair of first and second detection electrodes 114A and 114B is formed on the first surface 201 of the second detection arm 114 so as to be parallel to the longitudinal direction (the X axis direction) of the second detection arm 114.

That is, the vibration piece 100 of the modified example has a structure in which the vibration pieces 1 of the above-described embodiment commonly use the support portion 106, and are integrally formed with each other so as to be line-symmetrical to each other with respect to the imaginary central line extending in the Y axis direction (the first axis direction) of the support portion 106.

The substantial center of the support portion 106 is used as a support area 106A when the vibration piece 100 is bonded and fixed to the external unit. In the embodiment, the support area 106A is set about the gravity center G of the vibration piece 100. Accordingly, the vibration piece 100 fixed to the external unit may be supported with better balance.

Next, an exemplary mode of the operation of the vibration piece 100 will be described. Here, the mode of the operation of the vibration piece 100 when the first and second driving arms 2 and 3 are vibrated in a direction (+X direction) depicted by the arrows 2v and 3v, and the third and fourth driving arms 102 and 103 are vibrated in a direction (−X direction) depicted by the arrows 102v and 103v as shown in FIGS. 6A and 6B will be described.

First, as shown in FIG. 6A, if a counter-clockwise rotation coy about the Y axis is applied to the vibration piece 100 when the first and second driving arms 2 and 3 are vibrated in a direction (+X direction) depicted by the arrows 2v and 3v and the third and fourth driving arms 102 and 103 are vibrated in a direction (−X direction) depicted by the arrows 102v and 103v in accordance with the input of the excitation signal, Coriolis force is generated in the first and second driving arms 2 and 3 in a direction (+Z direction) depicted by reference numerals 2S1 and 3S1 perpendicular to the direction of the vibration (in-plane vibration), and Coriolis force is generated in the third and fourth driving arms 102 and 103 in a direction (−Z direction) depicted by reference numerals 102S1 and 103S1 perpendicular to the direction of the vibration.

Due to the Coriolis force, a vibration (out-of-plane vibration) is generated in the first and second detection arms 4 and 114 in a direction (+Z direction) depicted by reference numeral 114S1 and a direction (−Z direction) depicted by reference numeral 4S1 perpendicular to the first surface 201 (refer to FIG. 5).

When the amount of charge generated by the electric field components of the first and second detection arms 4 and 114 in accordance with the out-of-plane vibration is measured by the first and second detection electrodes 14A and 14B and the first and second detection electrodes 114A and 114B, the angular velocity when the rotation about the Y axis is applied to the vibration piece 100 may be obtained.

On the other hand, as shown in FIG. 6B, if a counter-clockwise rotation coz about the Z axis is applied to the vibration piece 100 when the first and second driving arms 2 and 3 are vibrated in a direction (+X direction) depicted by the arrows 2v and 3v and the third and fourth driving arms 102 and 103 are vibrated in a direction (−X direction) depicted by the arrows 102v and 103v, Coriolis force is generated in the first and second driving arms 2 and 3 in a direction (−Y direction) depicted by the arrows 2S2 and 3S2 perpendicular to the direction of the vibration (in-plane vibration), and Coriolis force is generated in the third and fourth driving arms 102 and 103 in a direction (+Y direction) depicted by reference numerals 102S2 and 103S2 perpendicular to the direction of the vibration.

Due to the Coriolis force, a vibration (in-plane vibration) is generated in the first detection arm 4 in a direction (+Y direction) depicted by the arrow 4S2 perpendicular to the direction depicted by the arrows 2v and 3v, and a vibration (in-plane vibration) is generated in the second detection arm 114 in a direction (−Y direction) depicted by reference numeral 114S2 perpendicular to the direction of the arrows 102v and 103v.

Then, the compressing or stretching in the reverse direction is generated in each of the first detection electrodes 14A and 114A and the second detection electrodes 14B and 114B of the first and second detection arms 4 and 114 by such in-plane vibration. When a difference in the amount of charge generated by the compressing or stretching of the first detection electrodes 14A and 114A and the second detection electrodes 14B and 114B is measured and calculated, the angular velocity when the rotation about the Z axis is applied to the vibration piece 100 may be obtained.

According to the vibration piece 100 of the modified example, the angular velocity may be detected with the better balance, and the number of driving arms and detection arms is twice that of the vibration piece 1 of the above-described embodiment, thereby achieving more highly precise detection of the angular velocity.

While the embodiment of the invention contrived by the inventor has been described in detail, the invention is not limited to the embodiment and the modified example thereof, and may be, of course, modified in various forms within the scope not departing from the spirit of the invention.

For example, the invention is not limited to the specific configurations described in the above-described embodiment and the modified example. For example, the shape or the like of the base portion, the driving armor the detection arm of the vibration piece 1, the connection bar, the support portion, and the like is not limited to the description.

In the same way, the position or the shape of the electrode, the wiring, the terminal, and the like is not limited to the above-described embodiment. Particularly, the electrode structure or arrangement of the first and second driving electrodes 12A, 12B, 13A, 13B, 112A, 112B, 113A, and 113B or the first and second detection electrodes 14A, 14B, 114A, and 114B is not limited to the above-described embodiment and the modified example. For example, the detection electrode may include two comb-shaped electrodes connecting one ends of plural electrode fingers through a common electrode, and the comb-shaped electrodes may be disposed while facing each other so as to prevent the contact between the electrode fingers, thereby forming a so-called crossed-finger electrode (IDT). In this case, the electrode fingers of the comb-shaped electrodes in the longitudinal direction may be disposed so as to be perpendicular to the longitudinal direction of the detection arms 4 and 114.

Further, in the above-described embodiment, a configuration has been described in which the IC chip 80 is connected to the inside of the package by wire bonding using the bonding wires 49. However, the invention is not limited thereto, and a configuration may be adopted in which an electronic component such as the IC chip 80 is bonded by other mounting methods, for example, face down bonding using a bonding member such as a metal bump or a conductive adhesive.

Furthermore, the vibration piece and the angular velocity sensor of the above-described embodiment and the modified example may be applied to an electronic apparatus such as a digital camera, a car navigation system, a cellular phone, a mobile PC, and a game controller. When the vibration piece and the angular velocity sensor of the above-described embodiment and the modified example are used, the angular velocity sensor may be installed so as not to be upright, thereby realizing a decrease in the height and size of the electronic apparatus.

The entire disclosure of Japanese Patent Application No. 2010-074983, filed Mar. 29, 2010 is expressly incorporated by reference herein.

What is claimed is:

1. A vibration piece comprising:
a base portion;
a first driving arm which extends in a first axis direction from one end of the base portion in the first axis direction;
a second driving arm which extends in the first axis direction from the other end of the base portion in the first axis direction;
driving electrodes which are respectively provided in the first driving arm and the second driving arm;
a detection arm which extends in a second axis direction perpendicular to the first axis direction from the base portion;
a detection electrode which is provided in the detection arm; and
a support portion which extends from the base portion,
wherein the support portion is provided so as to surround the detection arm.

2. The vibration piece according to claim 1, wherein the vibration piece is formed of a piezoelectric material.

3. The vibration piece according to claim 2, wherein the piezoelectric material is crystal.

4. The vibration piece according to claim 1,
wherein each of the driving electrodes and the detection electrode is a laminated structure including a first electrode, a second electrode, and a piezoelectric layer provided between the first electrode and the second electrode, and
wherein two laminated structures are provided on each of the first driving arm, the second driving arm, and the detection arm so as to be parallel to each other in the extension direction of each arm, the first electrode of one laminated structure is electrically connected to the second electrode of the other laminated structure, and the second electrode of one laminated structure is electrically connected to the first electrode of the other laminated structure.

5. The vibration piece according to claim 1, wherein the detection electrode is a pair of comb-shaped electrodes.

6. An angular velocity sensor comprising:
the vibration piece according to claim 1;
a driving section which drives the first and second driving arms in the same direction along the second axis direction; and
a detection section which detects a voltage, generated by a vibration generated in a third axis direction perpendicular to the first axis direction and the second axis direction in the detection arm when the rotation about the first axis is performed at the time of the driving operation, through the detection electrode.

7. An angular velocity sensor comprising:
the vibration piece according to claim 1;
a driving section which drives the first and second driving arms in the same direction along in the second axis direction; and
a detection section which detects a voltage, generated by a vibration generated in the first axis direction in the detection arm when the rotation about a third axis perpendicular to the first axis direction and the second axis direction is performed at the time of the driving operation, through the detection electrode.

8. An electronic apparatus comprising:
the vibration piece according to claim 1.
